(19) United States
(12) Patent Application Publication
(10) Pub. No.: US 2025/0022866 A1
(43) Pub. Date: Jan. 16, 2025

(54) SEMICONDUCTOR PACKAGE

(71) Applicant: Samsung Electronics Co., Ltd., Suwon-si (KR)

(72) Inventors: Sanghyeon JEONG, Suwon-si (KR); Hyunki KIM, Suwon-si (KR); Junga LEE, Suwon-si (KR)

(73) Assignee: Samsung Electronics Co., Ltd., Suwon-si (KR)

(21) Appl. No.: 18/409,931

(22) Filed: Jan. 11, 2024

(30) Foreign Application Priority Data
Jul. 14, 2023 (KR) 10-2023-0091816

(51) Int. Cl. H01L 25/18; H01L 23/498; H01L 23/00

(52) U.S. Cl. CPC H01L 25/18; H01L 23/49816; H01L 23/49822; H01L 23/49838; H01L 24/16; H01L 2224/16227; H01L 2924/182; H01L 2924/19105

(57) ABSTRACT

A semiconductor package includes a substrate, a passive element on the substrate, and a connection terminal connecting the substrate to the passive element. The substrate includes a base portion comprising an element pad connected to the connection terminal, and an upper insulating layer on the base portion to expose at least a portion of the base portion. The passive element is in contact with the upper insulating layer, and a thickness of the connection terminal and a thickness of the upper insulating layer are equal to each other.

### CROSS-REFERENCE TO RELATED APPLICATIONS

This U.S. non-provisional patent application claims priority under 35 U.S.C. § 119 to Korean Patent Application No. 10-2023-0091816, filed on Jul. 14, 2023, in the Korean Intellectual Property Office, the entire contents of which are hereby incorporated by reference.

### BACKGROUND OF THE INVENTION

The present disclosure relates to semiconductor packages, and more particularly, to semiconductor packages including a dam.

An integrated circuit chip may be realized in the form of a semiconductor package so as to be appropriately applied to an electronic product. Typically, a semiconductor chip may be mounted on a substrate such as a printed circuit board (PCB), thereby forming the semiconductor package. Various components in addition to the semiconductor chip may be coupled to the substrate of the semiconductor package. For example, a passive element such as a capacitor may be coupled to the substrate. The passive element may be coupled to the inside of the substrate, a top surface of the substrate or a bottom surface of the substrate to perform various functions.

### SUMMARY

Example embodiments of the inventive concepts may provide semiconductor packages with improved electrical characteristics and reliability.

In some aspects, a semiconductor package may include a substrate, a passive element on the substrate, and a connection terminal connecting the substrate to the passive element. The substrate may include a base portion comprising an element pad connected to the connection terminal, and an upper insulating layer on the base portion to expose at least a portion of the base portion. The passive element may be in contact with the upper insulating layer, and a thickness of the connection terminal and a thickness of the upper insulating layer may be about equal or equal to each other.

In some aspects, a semiconductor package may include a substrate, a passive element on the substrate, and a connection terminal connecting the substrate to the passive element. The substrate may include a base portion comprising an element pad connected to the connection terminal, and an upper insulating layer on the base portion to expose at least a portion of the base portion. The upper insulating layer may include a dam in contact with the passive element, and an insulating structure spaced apart from the passive element. The dam may be surrounded by the insulating structure.

In some aspects, a semiconductor package may include a substrate, a passive element on the substrate, a connection terminal connecting the substrate to the passive element, and a molding layer surrounding the passive element and the connection terminal. The substrate may include a base portion comprising an element pad connected to the connection terminal, and an upper insulating layer on the base portion to expose at least a portion of the base portion. The upper insulating layer may include a dam in contact with the passive element, and an insulating structure spaced apart from the passive element. The insulating structure may include a first sidewall extending in a first direction, a second sidewall extending in a second direction intersecting the first direction, and a corner at which the first sidewall meets the second sidewall. The dam may be in contact with the corner. The connection terminal, the insulating structure and the dam may be at a same level.

### BRIEF DESCRIPTION OF THE DRAWINGS

FIGS. 1A and 1B are plan views illustrating a semiconductor package according to some example embodiments of the inventive concepts.

FIG. 1C is a cross-sectional view taken along a line A-A′ of FIGS. 1A and 1B.

FIG. 2A is a plan view illustrating a semiconductor package according to some example embodiments of the inventive concepts.

FIG. 2B is a cross-sectional view taken along a line B-B′ of FIG. 2A.

FIG. 3 is a cross-sectional view illustrating a semiconductor package according to some example embodiments of the inventive concepts.

FIG. 4 is a plan view illustrating a semiconductor package according to some example embodiments of the inventive concepts.

FIG. 5 is a plan view illustrating a semiconductor package according to some example embodiments of the inventive concepts.

FIG. 6A is a plan view illustrating a semiconductor package according to some example embodiments of the inventive concepts.

FIG. 6B is a plan view illustrating a semiconductor package according to some example embodiments of the inventive concepts.

FIG. 7 is a cross-sectional view illustrating a semiconductor package according to some example embodiments of the inventive concepts.

### DETAILED DESCRIPTION

Example embodiments of the inventive concepts will now be described more fully with reference to the accompanying drawings.

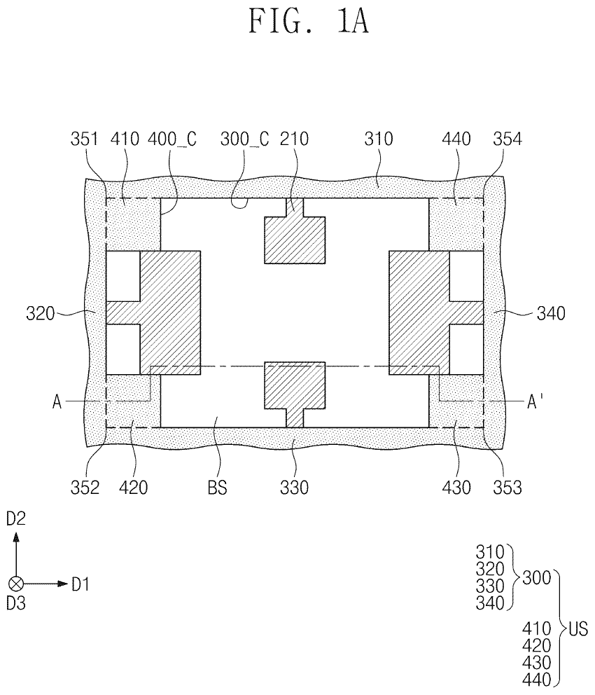

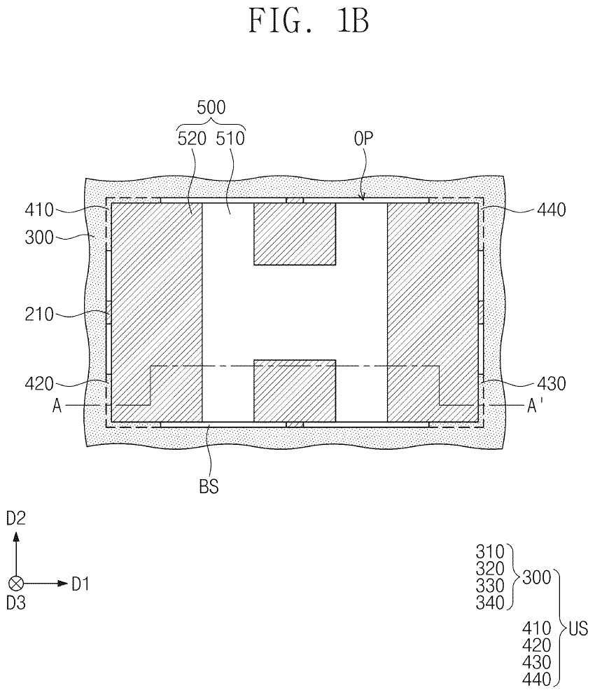

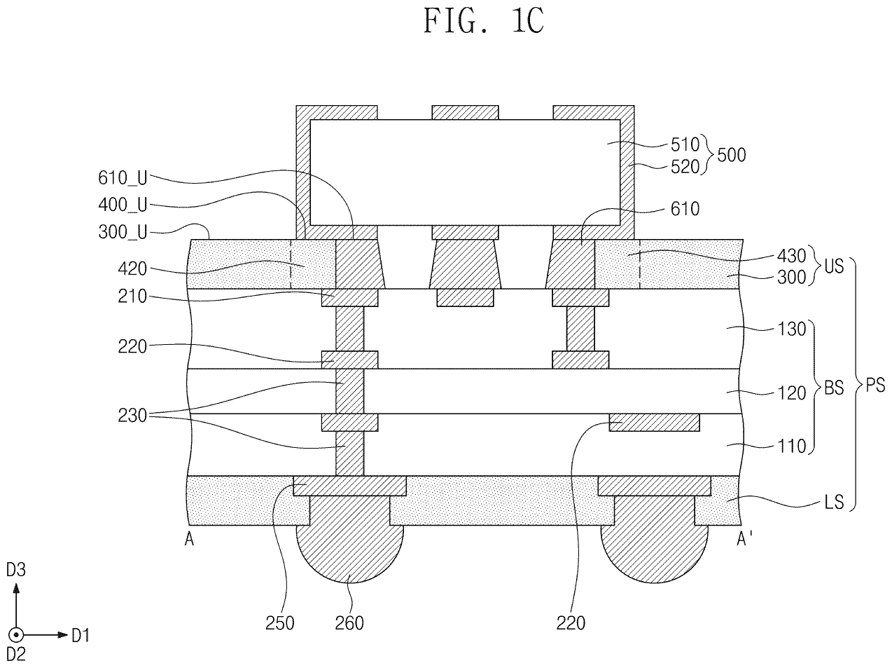

FIG. 1A is a plan view illustrating a semiconductor package before mounting a passive element, according to some example embodiments of the inventive concepts. FIG. 1B is a plan view illustrating a semiconductor package after mounting a passive element, according to some example embodiments of the inventive concepts. FIG. 1C is a cross-sectional view taken along a line A-A′ of FIGS. 1A and 1B.

Referring to FIGS. 1A, 1B and 1C, a semiconductor package may include a substrate PS, connection terminals 610, a passive element 500, and solder balls 260.

The substrate PS may be provided on the solder balls 260. The substrate PS may include a lower insulating layer LS, a base portion BS on the lower insulating layer LS, an upper insulating layer US on the base portion BS, element pads 210, conductive patterns 220, vias 230, and lower pads 250. The substrate PS may connect a semiconductor chip (not shown) to an external component. For example, the substrate PS may be a printed circuit board (PCB).

The base portion BS may have a plate shape extending along a plane extending in a first direction D1 and a second direction D2. The first direction D1 and the second direction D2 may intersect each other. For example, the first direction D1 and the second direction D2 may be horizontal directions perpendicular to each other. The base portion BS may include an insulating material. The base portion BS may include, but not limited to, a thermosetting resin (e.g., epoxy resin), a thermoplastic resin (e.g., polyimide), a resin (e.g., prepreg) obtained by impregnating the thermosetting resin or the thermoplastic resin with a reinforcing material (e.g., a glass fiber and/or an inorganic filler), and/or a photocurable resin.

In some example embodiments, the substrate PS may be a redistribution substrate including redistribution patterns.

The base portion BS may include a plurality of stacked substrate insulating layers 110, 120 and 130. The plurality of substrate insulating layers 110, 120 and 130 may be sequentially stacked in a third direction D3. The third direction D3 may intersect the first direction D1 and the second direction D2. For example, the third direction D3 may be a vertical direction perpendicular to the first direction D1 and the second direction D2. A second substrate insulating layer 120 may be disposed on a first substrate insulating layer 110, and a third substrate insulating layer 130 may be disposed on the second substrate insulating layer 120. However, the number of the substrate insulating layers 110, 120 and 130 is not limited to the illustrated number.

The lower insulating layer LS may be provided on a bottom surface of the first substrate insulating layer 110 of the base portion BS. The upper insulating layer US may be provided on a top surface of the third substrate insulating layer 130 of the base portion BS. For example, a thickness of the upper insulating layer US in the third direction D3 may range from about or exactly 10 μm to about or exactly 30 μm. At least a portion of a top surface of the base portion BS may be exposed by the upper insulating layer US.

The lower insulating layer LS and the upper insulating layer US may include an insulating polymer material. For example, the lower insulating layer LS and the upper insulating layer US may include a solder resist material. For example, the solder resist material may include epoxy or acrylate. The lower insulating layer LS and the upper insulating layer US may protect the base portion BS from the outside.

The element pads 210, the conductive patterns 220 and the vias 230 may be provided in the base portion BS.

The element pads 210 may be exposed above the base portion BS. At least portions of the element pads 210 may be exposed by the upper insulating layer US. The element pads 210 may be surrounded by the third substrate insulating layer 130.

The conductive patterns 220 may be provided in the base portion BS. The conductive patterns 220 may be surrounded by the first to third substrate insulating layers 110, 120 and 130. The conductive patterns 220 may have pad and/or line shapes.

The vias 230 may be provided in the base portion BS. The vias 230 may be surrounded by the first to third substrate insulating layers 110, 120 and 130.

The lower pads 250 may be provided on a bottom surface of the base portion BS. The lower pads 250 may be surrounded by the lower insulating layer LS. The lower pads 250 may be in contact with the solder balls 260.

The element pads 210, the conductive patterns 220, the vias 230 and the lower pads 250 may include a conductive material. For example, the element pads 210, the conductive patterns 220, the vias 230 and the lower pads 250 may include copper (Cu).

The solder balls 260 may be provided on the lower pads 250. The semiconductor package may be electrically connected to an external device through the solder balls 260. The solder balls 260 may include a conductive material.

The solder ball 260 may be connected to the lower pad 250. The lower pad 250 may be connected to the conductive pattern 220 through the via 230. The via 230 may connect the conductive patterns 220. The element pad 210 may be connected to the conductive pattern 220 through the via 230. The passive element 500 may be electrically connected to the vias 230 through the connection terminals 610 and the element pads 210.

The upper insulating layer US may include an insulating structure 300 on the base portion BS, and dams 410, 420, 430 and 440 surrounded by the insulating structure 300.

The insulating structure 300 may include first to fourth sidewalls 310, 320, 330 and 340. The first sidewall 310 and the third sidewall 330 may extend in the first direction D1. The first sidewall 310 and the third sidewall 330 may be spaced apart from each other in the second direction D2. The second sidewall 320 and the fourth sidewall 340 may extend in the second direction D2. The second sidewall 320 and the fourth sidewall 340 may be spaced apart from each other in the first direction D1.

The insulating structure 300 may include first to fourth corners 351, 352, 353 and 354. The first sidewall 310 and the second sidewall 320 may meet each other at the first corner 351. The second sidewall 320 and the third sidewall 330 may meet each other at the second corner 352. The third sidewall 330 and the fourth sidewall 340 may meet each other at the third corner 353. The first sidewall 310 and the fourth sidewall 340 may meet each other at the fourth corner 354.

The dams 410, 420, 430 and 440 may be in contact with the insulating structure 300 and the connection terminals 610. The dams 410, 420, 430 and 440 may be disposed between the passive element 500 and the base portion BS of the substrate PS. The dams 410, 420, 430 and 440 may be provided on the base portion BS of the substrate PS. In some example embodiments, the dam 410, 420, 430 or 440 may be provided on the element pad 210.

Each of the dams 410, 420, 430 and 440 may have a rectangular shape. For example, a width of each of the dams 410, 420, 430 and 440 in the first direction D1 and a length of each of the dams 410, 420, 430 and 440 in the second direction D2 may be about or exactly 3 mm or less (for example, between 0 mm and about or exactly 3 mm). However, example embodiments of the inventive concepts are not limited thereto, and in some example embodiments, each of the dams 410, 420, 430 and 440 may have a polygonal shape.

The dams 410, 420, 430 and 440 may include first to fourth dams 410, 420, 430 and 440. In some example embodiments, the number of the dams 410, 420, 430 and 440 may be less than three or may be five or more. For example, the number and shape of the dams may be related to the shape of the opening in the insulating structure 300, such as three triangular shaped dams in a triangular shaped opening.

Sizes of the first to fourth dams 410, 420, 430 and 440 may be about equal or equal to each other. However, example embodiments of the inventive concepts are not limited thereto, and in some example embodiments, sizes of the first to fourth dams 410, 420, 430 and 440 may be different from each other.

The insulating structure 300 and the dams 410, 420, 430 and 440 may include the same material. The insulating structure 300 and the dams 410, 420, 430 and 440 are described separately from each other, but the insulating structure 300 and the dams 410, 420, 430 and 440 may be connected to each other to constitute a single body structure without an interface therebetween, for example, they may be integral. In some example embodiments, the insulating structure 300 and the dams 410, 420, 430 and 440 may be formed using the same process. The dams 410, 420, 430 and 440 may be located at any positions on the top surface of the base portion BS, where the dams 410, 420, 430 and 440 are in contact with the passive element 500.

The insulating structure 300 may include an inner side surface 300_C. Each of the dams 410, 420, 430 and 440 may include a side surface 400_C. The inner side surface 300_C of the insulating structure 300 may meet the side surface 400_C of each of the dams 410, 420, 430 and 440. The inner side surface 300_C of the insulating structure 300 may be perpendicular to the side surface 400_C of each of the dams 410, 420, 430 and 440.

The connection terminals 610 may be provided on the element pads 210. The number and arrangement of the connection terminals 610 may be variously changed. The connection terminal 610 may be provided between the element pad 210 and the passive element 500. The connection terminal 610 may connect the element pad 210 and the passive element 500. The passive element 500 may be electrically connected to the substrate PS and the semiconductor chip (not shown) through the connection terminal 610. A side surface of the connection terminal 610 may be in contact with at least a portion of one of the side surfaces 400_C of the dam 410, 420, 430 or 440.

The connection terminal 610 may include a conductive material. For example, the connection terminal 610 may include a solder material. For example, the solder material may include tin, bismuth, lead, silver, and/or any alloy thereof.

The passive element 500 may be mounted on the substrate PS. The passive element 500 may be disposed on the dams 410, 420, 430 and 440 of the upper insulating layer US and the connection terminals 610. In some example embodiments, the passive element 500 may be coupled to the top surface of the substrate PS by surface mount technology (SMT). For example, the passive element 500 may include a capacitor (e.g., a die-side capacitor (DSC), a multi-layer ceramic capacitor (MLCC), or a low inductance chip capacitor (LICC)), or an inductor.

The passive element 500 may include an insulating portion 510 and a conductive portion 520. The conductive portion 520 of the passive element 500 may surround the insulating portion 510. The insulating portion 510 of the passive element 500 may include a dielectric material. The conductive portion 520 of the passive element 500 may include a conductive material. The conductive portion 520 of the passive element 500 may be in contact with the connection terminal 610. The conductive portion 520 of the passive element 500 may be electrically connected to the connection terminal 610.

The passive element 500 may be in contact with the upper insulating layer US. The passive element 500 may be in contact with the dams 410, 420, 430 and 440 of the upper insulating layer US. Each of the dams 410, 420, 430 and 440 may include a top surface 400_U. A portion of the top surface 400_U of each of the dams 410, 420, 430 and 440 may be in contact with the conductive portion 520 of the passive element 500. Another portion of the top surface 400_U of each of the dams 410, 420, 430 and 440 may not be in contact with the passive element 500. That is, in some example embodiments there may be a partial overlap of the top surface 400_U of each of the dams 410, 420, 430 and 440 and the passive element 500. The top surface 400_U of each of the dams 410, 420, 430 and 440 may be flat. The top surface 400_U of each of the dams 410, 420, 430 and 440 may be parallel to the first direction D1. The top surface 400_U of each of the dams 410, 420, 430 and 440 may be coplanar with a top surface 610_U of the connection terminal 610 and a top surface 300_U of the insulating structure 300.

The passive element 500 may be spaced apart from the insulating structure 300 of the upper insulating layer US. An opening OP may be formed between the insulating structure 300 and the passive element 500. A molding layer (not shown) may fill a space between the substrate PS and the passive element 500 through the opening OP.

The insulating structure 300, the dams 410, 420, 430 and 440 and the connection terminals 610 may be disposed at the same level. A level of the top surface of the insulating structure 300 may be the same as a level of a bottom surface of the passive element 500.

A thickness of the insulating structure 300, thicknesses of the dams 410, 420, 430 and 440 and a thickness of the connection terminal 610 may be about equal or equal to each other. For example, the thickness of the insulating structure 300, the thicknesses of the dams 410, 420, 430 and 440 and the thickness of the connection terminal 610 may range from about or exactly 10 μm to about or exactly 30 μm. In some example embodiments, the thickness of the insulating structure 300, the thicknesses of the dams 410, 420, 430 and 440 and the thickness of the connection terminal 610 may be greater than a size of a particle of the molding layer (not shown) disposed between the substrate PS and the passive element 500.

The semiconductor package according to some example embodiments may include the dams 410, 420, 430 and 440 supporting the passive element 500, and thus a load of the passive element 500 applied to the connection terminal 610 may be reduced. Thus, it is possible to prevent or reduce the connection terminal 610 from being pressed by the load of the passive element 500, and it is possible to secure a space between the passive element 500 and the substrate PS, which will be filled with the molding layer. Since the space between the passive element 500 and the substrate PS which will be filled with the molding layer is secured, occurrence of a void and delamination of the passive element 500 may be prevented or reduced to improve durability of the semiconductor package.

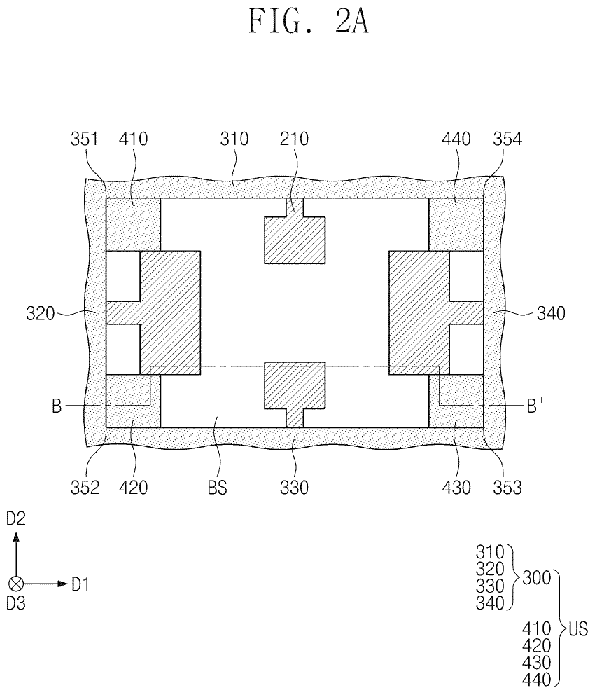

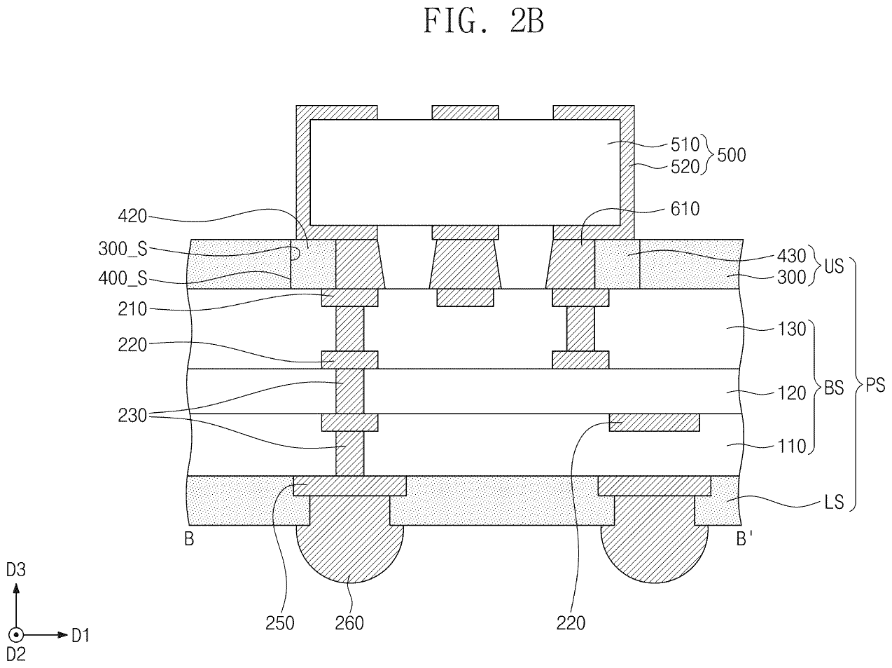

FIG. 2A is a plan view illustrating a semiconductor package before mounting a passive element, according to some example embodiments of the inventive concepts. FIG. 2B is a cross-sectional view taken along a line B-B′ of FIG. 2A to illustrate a semiconductor package after mounting a passive element, according to some example embodiments of the inventive concepts.

Referring to FIGS. 2A and 2B, a semiconductor package may include a substrate PS, connection terminals 610, a passive element 500, and solder balls 260.

The substrate PS may include a lower insulating layer LS, a base portion BS on the lower insulating layer LS, and an upper insulating layer US on the base portion BS.

The upper insulating layer US may include an insulating structure 300 including first to fourth sidewalls 310, 320, 330 and 340, and dams 410, 420, 430 and 440 surrounded by the insulating structure 300.

The insulating structure 300 may include a first corner 351 at which the first sidewall 310 meets the second sidewall 320, a second corner 352 at which the second sidewall 320 meets the third sidewall 330, a third corner 353 at which the third sidewall 330 meets the fourth sidewall 340, and a fourth corner 354 at which the first sidewall 310 meets the fourth sidewall 340.

The dams 410, 420, 430 and 440 may include a first dam 410 in contact with the first corner 351, a second dam 420 in contact with the second corner 352, a third dam 430 in contact with the third corner 353, and a fourth dam 440 in contact with the fourth corner 354. Boundaries may be provided between the insulating structure 300 and the dams 410, 420, 430 and 440. The insulating structure 300 may be distinguished from the dams 410, 420, 430 and 440 by the boundaries. The insulating structure 300 may include a material different from that of the dams 410, 420, 430 and 440. For example, the insulating structure 300 and the dams 410, 420, 430 and 440 may include different kinds of insulating materials. In some example embodiments, the insulating structure 300 and the dams 410, 420, 430 and 440 may be formed using different processes.

The first dam 410 may be in contact with the first sidewall 310 and the second sidewall 320 of the insulating structure 300, the second dam 420 may be in contact with the second sidewall 320 and the third sidewall 330 of the insulating structure 300, the third dam 430 may be in contact with the third sidewall 330 and the fourth sidewall 340 of the insulating structure 300, and the fourth dam 440 may be in contact with the first sidewall 310 and the fourth sidewall 340 of the insulating structure 300.

The boundaries between the insulating structure 300 and the dams 410, 420, 430 and 440 may be defined by an inner side surface 300_S of the insulating structure 300 and side surfaces 400_S of the dams 410, 420, 430 and 440.

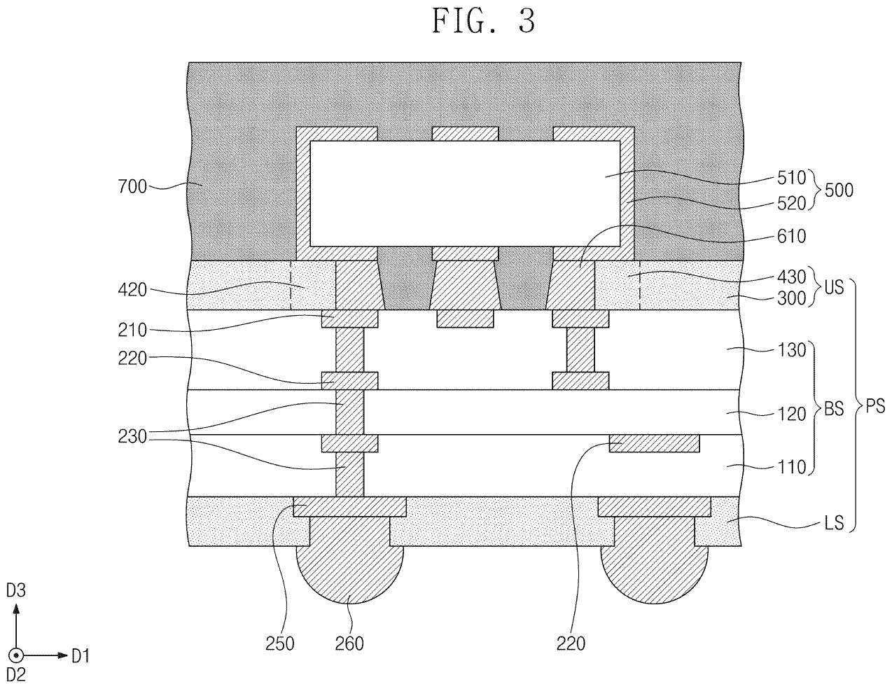

FIG. 3 is a cross-sectional view illustrating a semiconductor package according to some example embodiments of the inventive concepts.

Referring to FIG. 3, a semiconductor package may include a substrate PS, connection terminals 610, a passive element 500, solder balls 260, and a molding layer 700.

The substrate PS may include a lower insulating layer LS, a base portion BS on the lower insulating layer LS, and an upper insulating layer US on the base portion BS.

The molding layer 700 may be provided on the substrate PS. The molding layer 700 may cover the upper insulating layer US and at least a portion of the top surface of the base portion BS exposed by the upper insulating layer US. The molding layer 700 may be in contact with the exposed top surface of the base portion BS of the substrate PS. The molding layer 700 may surround the passive element 500. The molding layer 700 may cover a top surface and a side surface of the passive element 500. A portion of the molding layer 700 may be disposed between the passive element 500 and the base portion BS of the substrate PS. The molding layer 700 may protect the passive element 500 from external impact and heat.

The molding layer 700 may include an insulating material. For example, the molding layer 700 may include a polymer material. For example, the polymer material may include an epoxy molding compound (EMC).

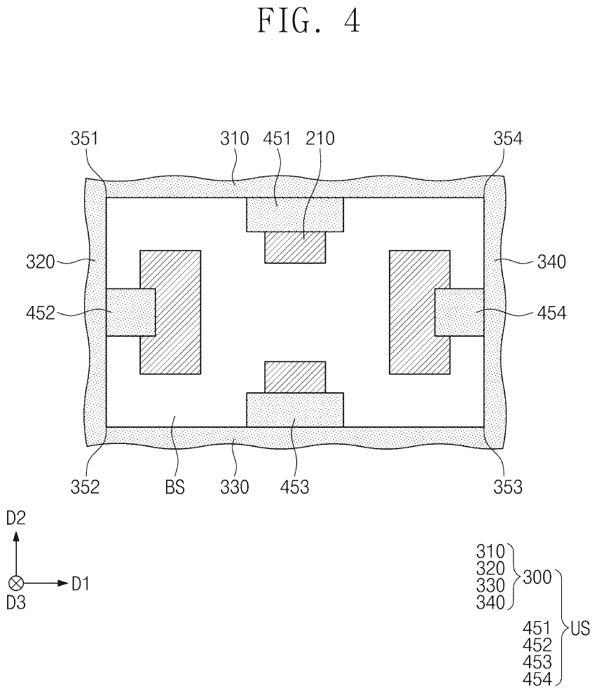

FIG. 4 is a plan view illustrating a semiconductor package before mounting a passive element, according to some example embodiments of the inventive concepts.

Referring to FIG. 4, a semiconductor package may include a base portion BS, an upper insulating layer US on the base portion BS, and element pads 210 in the base portion BS.

The upper insulating layer US may include an insulating structure 300 including first to fourth sidewalls 310, 320, 330 and 340, and dams 451, 452, 453 and 454 surrounded by the insulating structure 300.

The insulating structure 300 may include a first corner 351 at which the first sidewall 310 meets the second sidewall 320, a second corner 352 at which the second sidewall 320 meets the third sidewall 330, a third corner 353 at which the third sidewall 330 meets the fourth sidewall 340, and a fourth corner 354 at which the first sidewall 310 meets the fourth sidewall 340.

The dams 451, 452, 453 and 454 may include first to fourth sidewall dams 451, 452, 453 and 454. The first to fourth sidewall dams 451, 452, 453 and 454 may be disposed on the top surface of the base portion BS of the substrate PS and the element pads 210.

The first to fourth sidewall dams 451, 452, 453 and 454 may be in contact with the insulating structure 300. The first sidewall dam 451 may be in contact with the first sidewall 310 of the insulating structure 300. The second sidewall dam 452 may be in contact with the second sidewall 320 of the insulating structure 300. The third sidewall dam 453 may be in contact with the third sidewall 330 of the insulating structure 300. The fourth sidewall dam 454 may be in contact with the fourth sidewall 340 of the insulating structure 300.

The first sidewall dam 451 may be spaced apart from the first corner 351 and the fourth corner 354 of the insulating structure 300. The second sidewall dam 452 may be spaced apart from the first corner 351 and the second corner 352 of the insulating structure 300. The third sidewall dam 453 may be spaced apart from the second corner 352 and the third corner 353 of the insulating structure 300. The fourth sidewall dam 454 may be spaced apart from the third corner 353 and the fourth corner 354 of the insulating structure 300. For example, the first to fourth sidewall dams 451 to 454 may be about or exactly equidistant between the respective corners, or may be offset towards one corner or the other.

The passive element (not shown) may be disposed on the first to fourth sidewall dams 451, 452, 453 and 454. The first to fourth sidewall dams 451, 452, 453 and 454 may be in contact with the passive element (not shown).

Boundaries may be provided between the insulating structure 300 and the dams 451, 452, 453 and 454. The insulating structure 300 may be distinguished from the dams 451, 452, 453 and 454 by the boundaries. The insulating structure 300 may include a material different from that of the dams 451, 452, 453 and 454.

In some example embodiments, the insulating structure 300 and the dams 451, 452, 453 and 454 may include the same material. For example, the insulating structure 300 and the dams 451, 452, 453 and 454 are described separately from each other, but the insulating structure 300 and the dams 451, 452, 453 and 454 may be connected to each other to constitute a single body structure without boundaries therebetween, for example, the insulating structure 300 and the dams 451, 452, 453 and 454 may be integral.

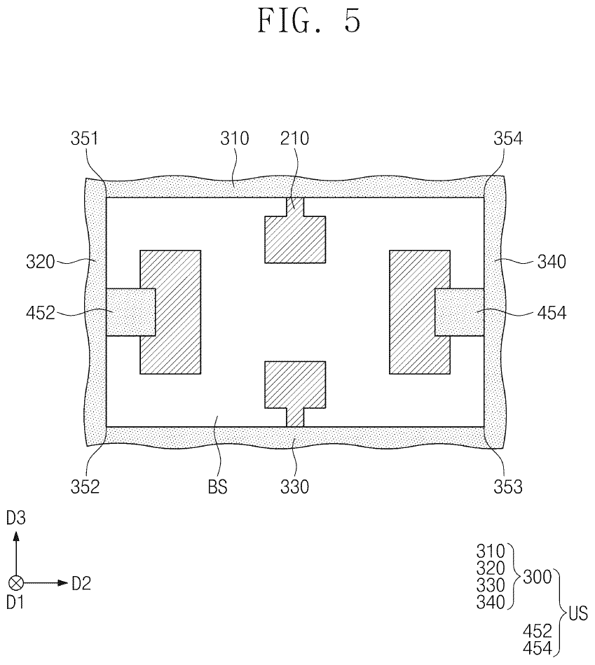

FIG. 5 is a plan view illustrating a semiconductor package before mounting a passive element, according to some example embodiments of the inventive concepts.

Referring to FIG. 5, a semiconductor package may include abase portion BS, an upper insulating layer US on the base portion BS, and element pads 210 in the base portion BS.

The upper insulating layer US may include an insulating structure 300 including first to fourth sidewalls 310, 320, 330 and 340 and first to fourth corners 351, 352, 353 and 354, and dams 452 and 454 surrounded by the insulating structure 300.

The dams 452 and 454 may not include the first sidewall dam in contact with the first sidewall 310, and the third sidewall dam in contact with the third sidewall 330. The dams 452 and 454 may include the second sidewall dam 452 in contact with the second sidewall 320, and the fourth sidewall dam 454 in contact with the fourth sidewall 340.

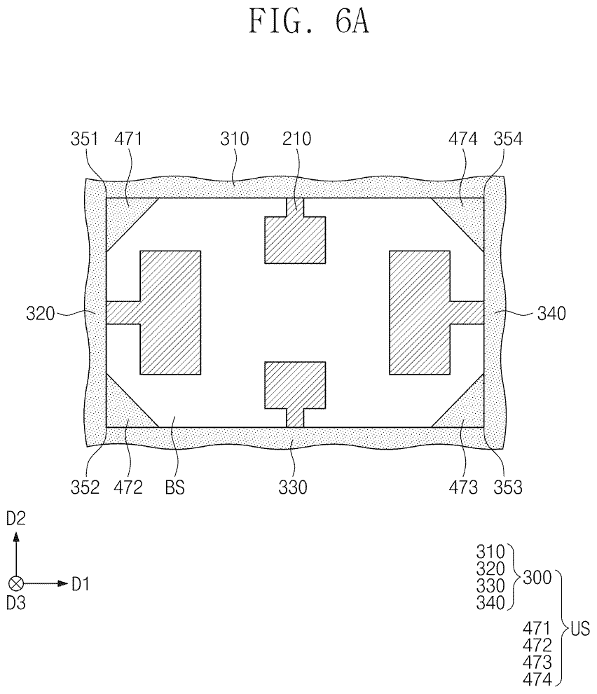

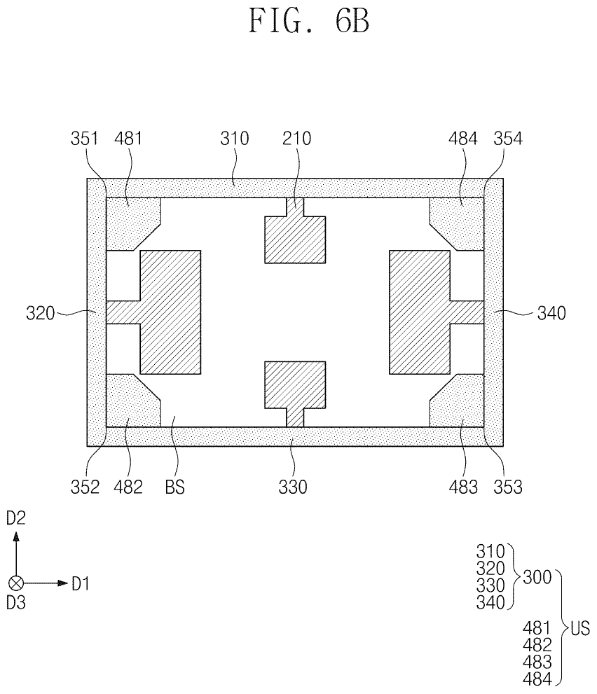

FIG. 6A is a plan view illustrating a semiconductor package before mounting a passive element, according to some example embodiments of the inventive concepts.

Referring to FIG. 6A, a semiconductor package may include a base portion BS, an upper insulating layer US on the base portion BS, and element pads 210 in the base portion BS.

The upper insulating layer US may include an insulating structure 300 including first to fourth sidewalls 310, 320, 330 and 340 and first to fourth corners 351, 352, 353 and 354, and dams 471, 472, 473 and 474 surrounded by the insulating structure 300.

The dams 471, 472, 473 and 474 may include first to fourth triangular dams 471, 472, 473 and 474. The first to fourth triangular dams 471, 472, 473 and 474 may have triangular shapes. For example, the first to fourth triangular dams 471, 472, 473 and 474 may have right triangle shapes having about equal or equal sizes. However, example embodiments of the inventive concepts are not limited thereto, and in some example embodiments, sizes of the first to fourth triangular dams 471, 472, 473 and 474 may be different from each other.

FIG. 6B is a plan view illustrating a semiconductor package before mounting a passive element, according to some example embodiments of the inventive concepts.

Referring to FIG. 6B, a semiconductor package may include a base portion BS, an upper insulating layer US on the base portion BS, and element pads 210 in the base portion BS.

The upper insulating layer US may include an insulating structure 300 including first to fourth sidewalls 310, 320, 330 and 340 and first to fourth corners 351, 352, 353 and 354, and dams 481, 482, 483 and 484 surrounded by the insulating structure 300.

The dams 481, 482, 483 and 484 may include first to fourth pentagonal dams 481, 482, 483 and 484. The first to fourth pentagonal dams 481, 482, 483 and 484 may have pentagonal shapes, and, for example, a corner of each of the first to fourth pentagonal dams 481, 482, 483 and 484 may align with a respective corner. For example, the first to fourth pentagonal dams 471, 482, 483 and 484 may have pentagonal shapes having about equal or equal sizes. However, example embodiments of the inventive concepts are not limited thereto, and in some example embodiments, sizes of the first to fourth pentagonal dams 481, 482, 483 and 484 may be different from each other.

The shapes of the dams 481, 482, 483 and 484 are not limited thereto but may be variously changed. For example, the dams 481, 482, 483 and 484 may have polygonal shapes.

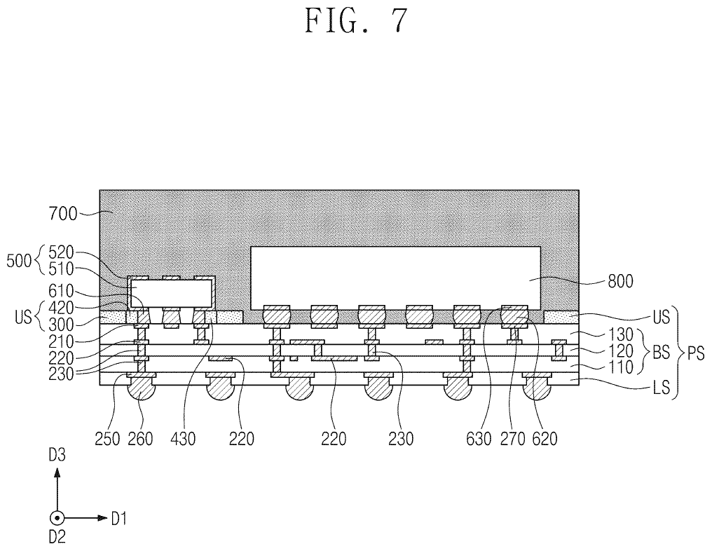

FIG. 7 is a cross-sectional view illustrating a semiconductor package according to some example embodiments of the inventive concepts.

Referring to FIG. 7, a semiconductor package may include a substrate PS, connection terminals 610, a passive element 500, solder balls 260, and a molding layer 700.

The substrate PS may include a lower insulating layer LS, a base portion BS including first to third substrate insulating layers 110, 120 and 130 on the lower insulating layer LS, and an upper insulating layer US on the base portion BS.

The base portion BS of the substrate PS may include element pads 210, conductive patterns 220, and vias 230.

The semiconductor package may further include upper pads 270, connection structures 620, chip pads 630, and a semiconductor chip 800.

The upper pads 270 may be provided in the base portion BS. The upper pads 270 may be exposed at the top surface of the base portion BS. The upper pads 270 may be surrounded by the third substrate insulating layer 130. The upper pad 270 may be connected to a corresponding one of the conductive patterns 220 through a corresponding one of the vias 230. The upper pad 270 may be electrically connected to the solder balls 260 through the conductive patterns 220 and the vias 230.

The semiconductor chip 800 may be mounted on the substrate PS. The semiconductor chip 800 may be provided on the top surface of the substrate PS. The semiconductor chip 800 may include a semiconductor device. For example, the semiconductor device may be a logic device. The semiconductor chip 800 may be spaced apart from the passive element 500 in the first direction D1. The semiconductor chip 800 may be spaced apart from the upper insulating layer US.

The chip pads 630 may be included in the semiconductor chip 800. The chip pads 630 may be exposed at a bottom surface of the semiconductor chip 800.

The connection structures 620 may be provided on the bottom surface of the semiconductor chip 800. The connection structures 620 may be provided between the substrate PS and the semiconductor chip 800. The connection structure 620 may connect the chip pad 630 in the semiconductor chip 800 to the upper pad 270 in the base portion BS. The connection structures 620 may connect the semiconductor chip 800 to the substrate PS. The semiconductor chip 800 may be electrically connected to the solder balls 260 through the connection structures 620.

The molding layer 700 may be in contact with the upper pads 270 exposed at the top surface of the base portion BS of the substrate PS and the chip pads 630 exposed at the bottom surface of the semiconductor chip 800. The molding layer 700 may surround the connection structures 620 and the semiconductor chip 800. The molding layer 700 may cover a top surface and a side surface of the semiconductor chip 800. A portion of the molding layer 700 may be disposed between the semiconductor chip 800 and the base portion BS of the substrate PS. The molding layer 700 may protect the semiconductor chip 800 from external impact and heat.

In the semiconductor package according to some example embodiments of the inventive concepts, the upper insulating layer may include the dam supporting the passive element, and thus it is possible to secure the space between the passive element and the substrate, which will be filled with the molding layer. As a result, delamination of the passive element may be prevented or reduced.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

While the example embodiments of the inventive concepts have been particularly shown and described, it will be understood by one of ordinary skill in the art that variations in form and detail may be made therein without departing from the spirit and scope of the attached claims.

What is claimed is:

1. A semiconductor package comprising:
a substrate;
a passive element on the substrate; and
a connection terminal connecting the substrate to the passive element,
the substrate comprising
a base portion comprising an element pad connected to the connection terminal; and
an upper insulating layer on the base portion to expose at least a portion of the base portion,
the passive element in contact with the upper insulating layer, and
a thickness of the connection terminal and a thickness of the upper insulating layer being equal to each other.

2. The semiconductor package of claim 1, wherein the thickness of the upper insulating layer is 30 μm or less.

3. The semiconductor package of claim 1, wherein
the passive element includes an insulating portion and a conductive portion surrounding the insulating portion, and
the conductive portion is electrically connected to the connection terminal.

4. The semiconductor package of claim 1, further comprising:
a semiconductor chip on the substrate and spaced apart from the passive element in a first direction; and
a connection structure connecting the substrate to the semiconductor chip,
wherein the upper insulating layer is spaced apart from the semiconductor chip.

5. The semiconductor package of claim 1, wherein
the substrate further comprises vias penetrating the base portion, and
the passive element is electrically connected to the vias through the connection terminal and the element pad.

6. The semiconductor package of claim 1, wherein
the upper insulating layer comprises an insulating structure and a dam,
the passive element is in contact with the dam, and
the passive element is spaced apart from the insulating structure.

7. The semiconductor package of claim 6, wherein a shape of the dam is a polygonal shape.

8. The semiconductor package of claim 6, wherein the dam includes a plurality of dams.

9. The semiconductor package of claim 6, wherein
the insulating structure includes:
a first sidewall extending in a first direction;
a second sidewall extending in a second direction intersecting the first direction; and
a corner at which the first sidewall meets the second sidewall, and
the dam is in contact with the corner.

10. The semiconductor package of claim 6, wherein
the insulating structure and the dam include a same material, and
the insulating structure and the dam are connected to each other without a boundary therebetween.

11. A semiconductor package comprising:
a substrate;
a passive element on the substrate; and
a connection terminal connecting the substrate to the passive element,
the substrate comprising a base portion comprising an element pad connected to the connection terminal; and
an upper insulating layer on the base portion to expose at least a portion of the base portion,
the upper insulating layer comprising
a dam in contact with the passive element; and
an insulating structure spaced apart from the passive element, and
the dam being surrounded by the insulating structure.

12. The semiconductor package of claim 11, wherein
the insulating structure includes:
a first sidewall extending in a first direction;
a second sidewall extending in a second direction intersecting the first direction;
a third sidewall spaced apart from the first sidewall in the second direction;
a fourth sidewall spaced apart from the second sidewall in the first direction,
a first corner at which the first sidewall meets the second sidewall;
a second corner at which the second sidewall meets the third sidewall;
a third corner at which the third sidewall meets the fourth sidewall; and
a fourth corner at which the first sidewall meets the fourth sidewall.

13. The semiconductor package of claim 12, wherein
the dam includes first to fourth dams on the substrate,
the first dam is in contact with the first corner,
the second dam is in contact with the second corner,
the third dam is in contact with the third corner, and
the fourth dam is in contact with the fourth corner.

14. The semiconductor package of claim 12, wherein
the element pad includes a plurality of element pads,
the dam includes first and second dams on the element pads,
the first dam is in contact with the second sidewall and is spaced apart from the first corner and the second corner, and
the second dam is in contact with the fourth sidewall and is spaced apart from the third corner and the fourth corner.

15. The semiconductor package of claim 12, wherein
the element pad includes a plurality of element pads,
the dam includes first to fourth dams on the element pads,
the first dam is in contact with the first sidewall and is spaced apart from the first corner and the fourth corner,
the second dam is in contact with the second sidewall and is spaced apart from the first corner and the second corner,
the third dam is in contact with the third sidewall and is spaced apart from the second corner and the third corner, and
the fourth dam is in contact with the fourth sidewall and is spaced apart from the third corner and the fourth corner.

16. The semiconductor package of claim 11, wherein
a width of the dam in a first direction is 3 mm or less, and
a length of the dam in a second direction intersecting the first direction is 3 mm or less.

17. The semiconductor package of claim 11, wherein a level of a top surface of the insulating structure is a same level as a level of a bottom surface of the passive element.

18. The semiconductor package of claim 11, wherein thicknesses of the connection terminal, the insulating structure and the dam are equal to each other.

19. A semiconductor package comprising:
a substrate;
a passive element on the substrate;
a connection terminal connecting the substrate to the passive element; and
a molding layer surrounding the passive element and the connection terminal,
the substrate comprising
a base portion comprising an element pad connected to the connection terminal; and
an upper insulating layer on the base portion to expose at least a portion of the base portion,
the upper insulating layer comprising
a dam in contact with the passive element; and
an insulating structure spaced apart from the passive element,
the insulating structure including
a first sidewall extending in a first direction;
a second sidewall extending in a second direction intersecting the first direction; and
a corner at which the first sidewall meets the second sidewall,
the dam in contact with the corner, and
the connection terminal, the insulating structure and the dam are at a same level.

20. The semiconductor package of claim 19, wherein the insulating structure and the dam include different insulating materials.
